(19) United States
(12) Patent Application Publication
(10) Pub. No.: US 2004/0137700 A1
(43) Pub. Date: Jul. 15, 2004

(54) Method for dividing semiconductor wafer

(76) Inventor: Kazuma Sekiya, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/475,676

(22) PCT Filed: Feb. 6, 2003
(86) PCT No.: PCT/JP03/01235

(30) Foreign Application Priority Data
Feb. 25, 2002 (JP) 2002-47864

(51) Int. Cl. H01L 21/301; H01L 21/46; H01L 21/78

(52) U.S. Cl. 438/460; 438/463

(57) ABSTRACT

In dicing a semiconductor wafer W into separate chips, each having a circuit pattern formed therein, the semiconductor wafer W is masked with a masking member 15 to cover at least the front face of the semiconductor wafer on which the circuit patterns are formed and delimited by crosswise streets S. A laser beam is irradiated to selectively remove the crosswise portion of the masking member 15 which is exactly aligned with the underlying crosswise streets S of the semiconductor wafer W. Then, the semiconductor wafer W whose crosswise streets are unmasked is chemically etched so that the crosswise streets may erode to divide the semiconductor wafer W into chips C. Photomasks and an exposure apparatus are not required, thus providing the financial advantage and simplifying the treatment required for dicing. Also advantageously semiconductor chips provided are free of cracks on their edges, or free of interlayer insulating films being peeled-off, which would be caused if semiconductor wafers were diced by cutters.

### TECHNICAL FIELD

The present invention relates to a dicing method using a chemical etching treatment to separate a semiconductor wafer into chips.

### BACKGROUND ART

Referring to FIG. 10, a semiconductor wafer W is combined with a frame F as a whole unit, with an adhesive tape T applied therebetween. The semiconductor wafer W has crosswise streets S formed on its front surface. These streets are arranged at regular intervals in the form of lattice to define a lot of rectangular regions each having a circuit pattern formed therein. A rotary blade is used to cut the semiconductor wafer W along the crosswise streets S into separate semiconductor chips.

Semiconductor chips, however, are often cracked or inner-stressed on their edges by the rotary blades. Such defects are apt to reduce their flexural strength so that they may be susceptible to undesired outer force or thermal cyclic influence to be damaged or shortened in life. This is increasingly conspicuous with semiconductor wafers having a thickness of 50 μm or less, and such cracks or inner stresses are almost fatal to thin semiconductor wafers.

In the hope of dealing with this problem, the semiconductor wafer dicing method using chemical etching has been studied and proposed. It comprises the steps of: coating a semiconductor wafer W with a photo-resistive material; applying a photomask to the photo-resistive coating of the semiconductor wafer W to expose to light the coating portion which is aligned with the underlying crosswise streets; removing the crosswise pattern thus exposed and changed in properties from the photo-resistive coating; and eroding the semiconductor wafer in its streets to separate into semiconductor chips.

However, in order to expose the photo-resist to light in the method stated above, it is required to prepare a plurality of photomasks whose lattice patterns and sizes are different to exactly conform to different semiconductor wafers to be diced. This is disadvantageous from the economical point of view. Also, a complicated problem is caused in management.

Still disadvantageously, it is necessary to install an exposure apparatus which can precisely align a semiconductor wafer with the overlying photomask in respect of their lattice patterns. In addition, it is necessary to install a coating removal apparatus for selectively removing the portion of the photo-resistive coating which was exposed to light and changed in properties in the form of lattice pattern. Such extra apparatuses cost much in investment.

In case patterns such as an alignment mark are formed on the streets of a semiconductor wafer W with a material which cannot be removed by a chemical etching treatment, the semiconductor wafer W actually cannot be diced by the etching treatment.

To solve this problem, it has been proposed that a rotary blade is used to selectively and mechanically remove the lattice patterned portion from the overlying coating to permit the chemical etching on the semiconductor wafer for dicing, e.g. as disclosed in JP 2001-127011A.

The selective mechanical removal of the coating with the rotary blade, however, may crack semiconductor chips on their edges, thereby reducing their flexural strength. Particularly in case of cutting a semiconductor wafer having multi-layered structure with a plurality of very thin insulating films (low dielectric-constant films) interleaved with the laminations, if the rotary blade cuts somewhat deeper than required into thin insulating films, some thin insulating films are apt to be peeled off from the semiconductor wafer, as in a mica plate.

In view of the above, an object of the present invention is to provide a method for dicing semiconductor wafer with a chemical etching treatment which is guaranteed to be free from cracking semiconductor chips on their edges and free from causing inner-stresses therein without involving extra cost.

### DISCLOSURE OF INVENTION

A method for dicing a semiconductor wafer having regions defined by crosswise streets into separate chips, each of the regions having a circuit pattern formed therein according to the present invention comprises a masking step of masking the semiconductor wafer with a masking member to cover the front face of the semiconductor wafer on which the circuit patterns formed; a selective mask-removing step of irradiating a laser beam to selectively remove crosswise portions of the masking member which are exactly aligned with the underlying crosswise streets of the semiconductor wafer; and a chemical etching step of chemically etching the semiconductor wafer having the crosswise streets unmasked, whereby the crosswise streets are permitted to erode so that the semiconductor wafer is divided into chips.

The selective mask-removing step may include the steps of: prior to crosswise removal of the masking member with the laser beam, making grooves along the underlying crosswise streets in the masking member to leave a constant thickness of masking member remaining under the crosswise grooves; and irradiating the laser beam to bottoms of the crosswise grooves to remove the remaining thickness of the masking member. The semiconductor wafer may have a plurality of circuit-patterned laminations and interlayer insulating films both interleaved with each other on its substrate. If a cover layer which cannot be removed by the chemical etching is formed on the crosswise street pattern, the laser beam may be irradiated to the cover layer for selective removal in the selective mask-removing step, thereby exposing the crosswise streets prior to the chemical etching step. The chemical etching in the chemical etching step may be dry etching with use of a fluoride gas. Semiconductor wafers to be diced may have a thickness of 50 μm or less.

As described above, a semiconductor wafer is masked with a masking member to cover its front face on which a circuit pattern is formed; the crosswise portion of the masking member lying on the crosswise streets of the semiconductor wafer is exposed to a laser beam to be removed; and thereafter the unmasked portion is chemically etched to separate the semiconductor wafer into chips. Therefore, neither photomasks nor exposing apparatus are required, and semiconductor chips thus provided are free of cracks or any other defects, and high in flexural strength.

In dicing a multi-layered semiconductor wafer with very thin interlayer insulating films, any impact, which would be caused by cutting with use of a rotary blade, cannot be applied to the interlayer insulating films, and therefore, there is no fear of insulating leaves falling off as in a mica plate.

In selectively unmasking the masked semiconductor wafer in the form of lattice, the cutting means is used to make the crosswise grooves in the masking member in conformity with the underlying crosswise streets, leaving a constant thickness of mask material of the masking member remaining on each underlying street, thus allowing a laser beam to scan the crosswise grooves to remove the remaining thickness of mask material, while a scanning speed and an operating voltage of the laser beam can be kept constant without the necessity of changing or varying the scanning speed and the operating voltage.

### BRIEF DESCRIPTION OF DRAWINGS

FIG. 1A illustrates a semiconductor wafer just after the masking step;

FIG. 1B illustrates the semiconductor wafer just after the selective mask-removing step;

FIG. 1C illustrates the semiconductor wafer just after the chemical etching step;

FIG. 2 is a perspective view of a spin coater;

FIG. 3 is a perspective view of a laser machining apparatus for use in the selective mask-removing step;

FIG. 4 is a perspective view of a dry-etching apparatus for use in the chemical etching step;

FIG. 5 is a sectional view of the wafer taking-in and -out chamber of the dry-etching treatment chamber of the dry-etching apparatus;

FIG. 6 shows the structure of the dry-etching treatment chamber and a gas supply unit of the dry-etching apparatus;

FIG. 7A illustrates a semiconductor wafer W just after the masking step;

FIG. 7B illustrates the semiconductor wafer W just after making grooves at an early part of the selective mask-removing step;

FIG. 7C illustrates the semiconductor wafer W just after selectively unmasked;

FIG. 7D illustrates the semiconductor wafer W just after being chemically etched;

FIG. 8 is a perspective view of a cutting apparatus to be used in making grooves at the early part of the selective mask-removing step;

FIG. 9 illustrates how the cutter means of the cutting apparatus can be put in the reference position; and

FIG. 10 illustrates a combination of a semiconductor wafer and a frame stuck together with an adhesive tape.

### BEST MODE FOR CARRYING OUT THE INVENTION

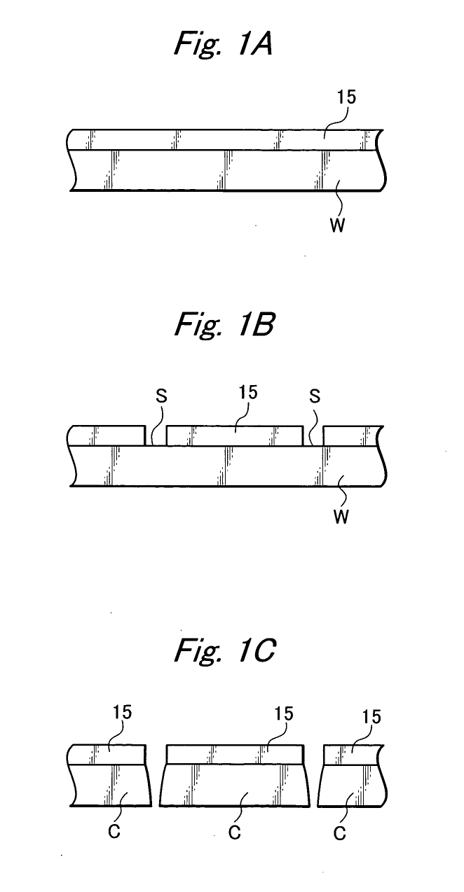

Referring to FIGS. 1A to 6, one of best embodiments of the present invention is described below. FIGS. 1A, 1B and 1C show the sequential steps of dicing a semiconductor wafer according to the present invention. Specifically, FIG. 1A illustrates the semiconductor wafer W after finishing the masking step; FIG. 1B illustrates the semiconductor wafer W after finishing the selective mask-removing step; and finally FIG. 1C illustrates the semiconductor wafer W after finishing the chemical etching step.

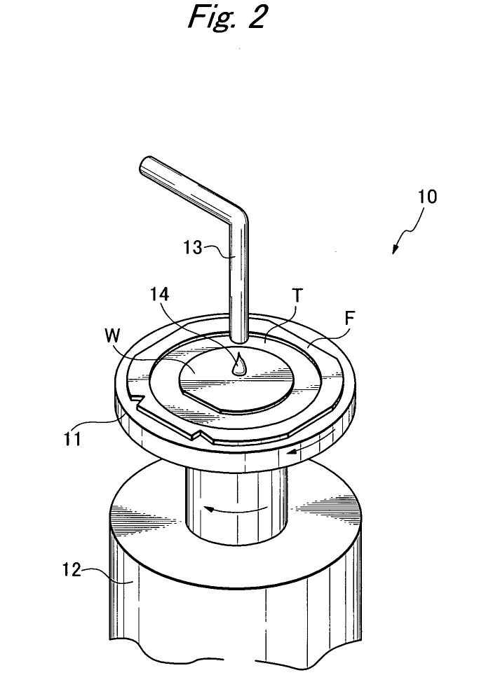

First at the masking step, a masking member 15 is formed on the semiconductor wafer W, for example, with use of a spin coater 10 as shown in FIG. 2. A holder table 11 for fixedly holding the semiconductor wafer W can be rotated by a drive means 12. The semiconductor wafer W is fixed to an associated frame F by an adhesive tape T applied to the rear face of the semiconductor wafer W and the frame F. Specifically, the adhesive tape T traverses the opening of the frame F, sticking to the rear face of the semiconductor wafer W. The semiconductor wafer W combined with the frame F as a whole unit via the adhesive tape T is held on the holder table 11 with the front face up.

While rotating the holder table 11 at a high speed, a drop of resist polymer 14 falls on the front face of the semiconductor wafer on which an electric circuit pattern is formed. Thus, the front face of the semiconductor wafer W is coated with the resist polymer (masking step). The masking member 15 is thin enough to allow the subsequent step to be carried out with efficiency, e.g., 10 to 50 μm thick.

The masking member 15 should not be understood as being limitative. Alternatively an adhesive tape can be used as a masking member 15.

At the selective mask-removing step, the portions of the masking member 15 which lie on the crosswise streets of the semiconductor wafer W are removed from the masking member 15.

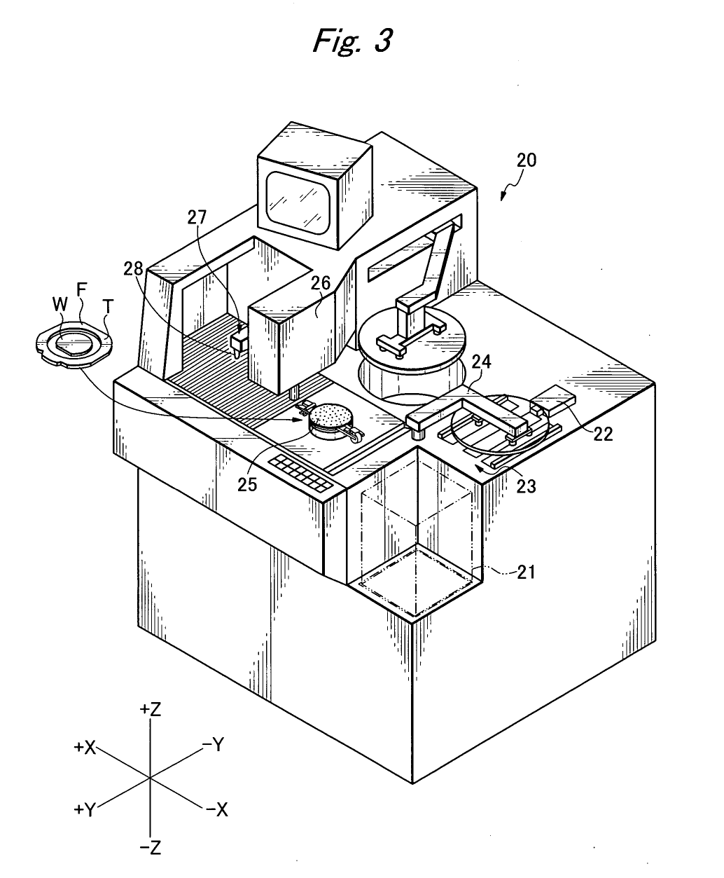

A laser machining apparatus 20 of FIG. 3 is used at the selective mask-removing step. A plurality of the semiconductor wafers W each of which is combined with a frame F as a whole unit via an adhesive tape T and covered the front face with the masking member 15 are stored in a cassette 21 of the laser machining apparatus 20.

The semiconductor wafer W combined with a frame F as a whole unit and covered the front face is transported one by one from the cassette 21 to a tentative depository 23 by a transporting means 22 and transported by a transfer means 24 while being sucked thereto to a chuck table 25 to be held thereon.

Then, the chuck table 25 is moved in the +X-direction, and the semiconductor wafer W is put below an alignment means 26, which detects a selected street. A projector 28 of a laser beam radiating means 27 is put in alignment with the so detected street in respect of the Y-axial direction. If a semi-transparent masking member 15 is applied on the front face of the semiconductor wafer, infrared rays are used to pass through the masking member 15 for detecting a selected street.

After the required alignment is finished, the chuck table 25 is moved further in the +X-direction, allowing the laser beam to irradiate the portions of the masking member 15 aligned with the detected street. Thus, the overlying linear strip is removed from the masking member 15.

Every time the laser beam radiating means 27 is driven the street-to-street distance in the Y-axial direction, the chuck table 25 is reciprocated in the X-axial direction, thereby removing each and every linear section of the masking member lying on the X-axial streets.

Then, the chuck able 25 is rotated 90 degrees, and the laser beam is made to scan the semiconductor wafer in the same way as described above. Thus, the crosswise portion of the masking member 15 lying on the crosswise streets S is removed, as seen from FIG. 1B (selective mask-removing step).

The selective mask-removing step using the laser beam does not require any photomask, exposing apparatus and removing apparatus which are required in the conventional light-exposure unmasking process. In addition to the economical advantage provided by the selective mask-removing step using the laser beam, it can be carried out at an increased efficiency, compared with the conventional light-exposure unmasking process.

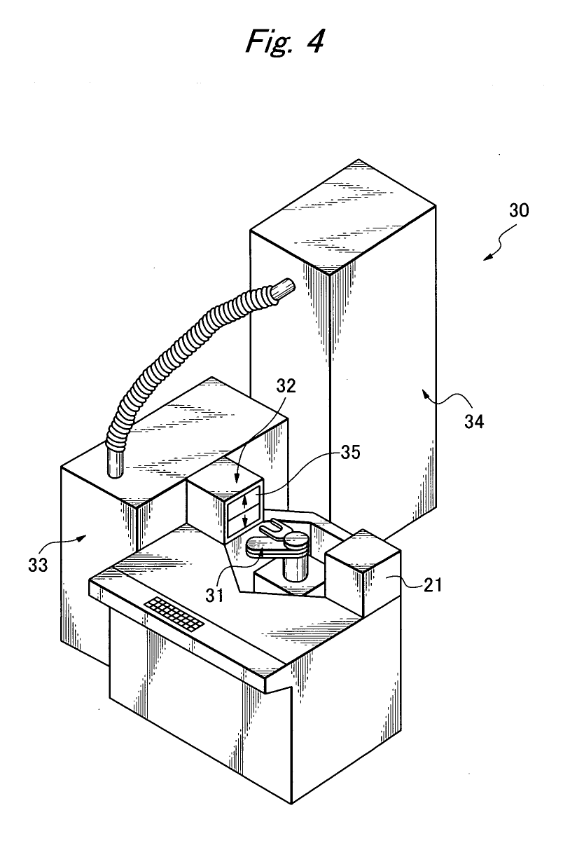

When the selective mask-removing step is completed on all the semiconductor wafers, they are contained in the cassette 21, and the cassette 21 is transported to the chemical etching section. A dry-etching apparatus 30 as shown in FIG. 4 is used in carrying out the chemical etching step.

Referring to FIG. 4, the dry-etching apparatus 30 comprises: a wafer taking-in and -out means 31 for taking out selectively unmasked semiconductor wafers W from the cassette 21 and for putting chemically-etched wafers W in the cassette 21; a wafer taking-in and -out chamber 32 for receiving semiconductor wafers W from the wafer taking-in and -out means 31 and for storing the semiconductor wafers in the chamber 32; a dry-etching treatment chamber 33; and a gas supply 34 for feeding the dry-etching treatment chamber 33 with etching gas.

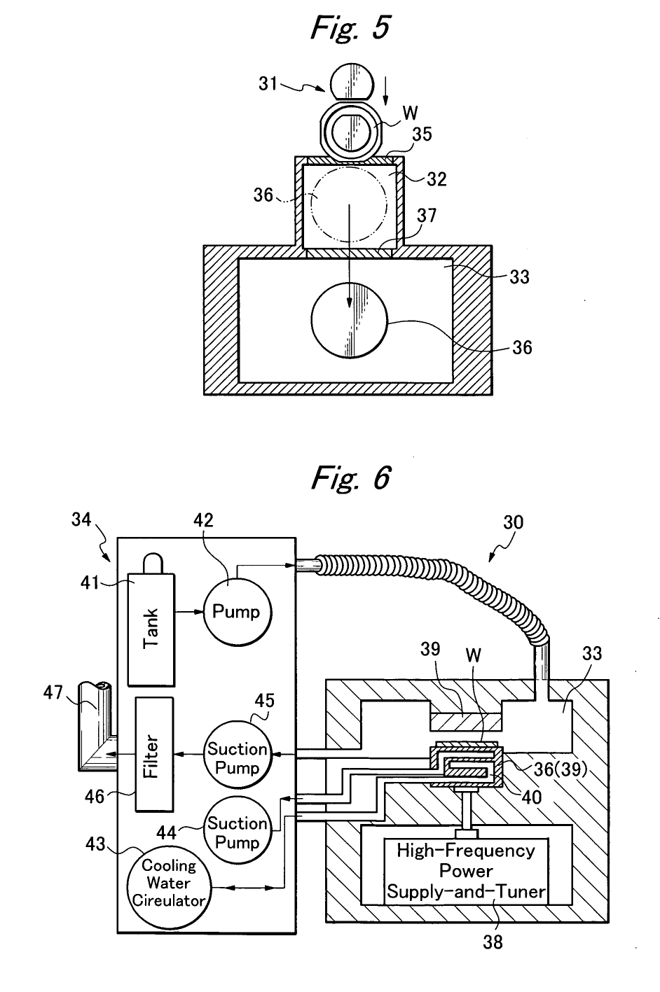

The wafer taking-in and -out means 31 takes out selectively-unmasked semiconductor wafers W one by one from the cassette 21. Then, a first gate 35 of the wafer taking-in and -out chamber 32 is opened, allowing the semiconductor wafer W to be laid on a holder 36 in the chamber 32 as shown in FIG. 5.

As seen from FIG. 5, the wafer taking-in and -out chamber 32 is isolated from the dry-etching treatment chamber 33 by a second gate 37. The holder 36 is responsive to the opening of the second gate 37 for moving from the wafer taking-in and -out chamber 32 to the dry-etching treatment chamber 33 or vice versa.

As seen from FIG. 6, upper and lower electrodes 39 are connected to a high-frequency power supply-and-tuner unit 38 in the dry-etching treatment chamber 33. In this particular example one of the opposite electrodes 39 takes the part of the holder 36. The holder 36 is equipped with a cooling means 40 for cooling the semiconductor wafer W.

The gas supply 34 comprises a tank 41 for storing etching gas, a pump 42 for directing the etching gas from the tank 41 to the dry-etching treatment chamber 33, a coolant circulator 43 for supplying cooling water to the cooling means 40, a suction pump 44 for applying negative pressure to the holder 36, another suction pump 45 for sucking the etching gas from the dry-etching treatment chamber 33, and a filter 46 for neutralizing the used etching gas sucked by the suction pump 45 and for draining the so neutralized etching gas through a drain 47.

When dry-etching the selectively unmasked semiconductor wafer W, the first gate 35 of the wafer taking-in and -out chamber 32 is opened, and the wafer taking-in and -out means 31 carries a selected unmasked semiconductor wafer W in the direction indicated by the arrow in FIG. 5 to put it on the holder 36 in the chamber 32 with its front face up. Then, the first gate 35 is closed to evacuate the chamber 32.

Then, the second gate 37 is opened to allow the holder 36 to move into the dry-etching treatment chamber 33. Thus, the semiconductor wafer W is put in the chamber 33, in which it is dry-etched by feeding the chamber 33 with an etching gas such as a thin fluoric gas by using the pump 42, and by applying the high-frequency voltage to the high-frequency electrodes 39 from the high-frequency power supply-and-tuner 38, thereby generating a plasma over the semiconductor wafer W for dry etching. At the same time, cooling water is supplied from the coolant circulator 43 to the cooling means 40.

The unmasked portion of the semiconductor wafer W is dry-etched, so that the crosswise streets may erode to divide the semiconductor wafer into the chips, as seen from FIG. 1C (chemical etching step).

After etching the used etching gas is drawn from the dry-etching treatment chamber 33 by the suction pump 45, and it is neutralized in the filter 46 to be drained away through the drain 47. Then, the chamber 33 is evacuated, and then, the second gate 37 is opened, thereby allowing the holder 36 to carry the dry-etched semiconductor wafer W into the wafer taking-in and -out chamber 32. Then, the second gate 37 is closed.

When the dry-etched semiconductor wafer W is moved into the chamber 32, the first gate 35 is opened, and the taking-in and -out means 31 transfers the dry-etched semiconductor wafer W from the chamber 32 to the cassette 21.

All the semiconductor wafers are treated as described above, and all the diced semiconductor wafers are put in the cassette 21. Then, the respective semiconductor chips C thus provided are unmasked and cleaned by using an appropriate solvent.

The semiconductor chips C are free of any defects such as cracks or inner stresses, which would be caused if the semiconductor wafers were diced with a rotary cutter. Such defects are most likely to be caused for semiconductor wafers having a thickness of 50 μm or less. The dry-etching method can be advantageously used in dicing such thin semiconductor wafers.

Also, in case of dicing a semiconductor wafer W having multi-layered structure with a plurality of very thin interlayer insulating films interleaved with the laminations, the laser beam scanning the semiconductor wafer for selective unmasking does not apply any force to the interlayer insulating films, comparing a case of dicing with use of a rotary blade. Therefore, there is no fear of insulating films being peeled off like a mica plate.

As is well known, the time involved for dry etching increases with the thickness of the semiconductor wafer to be treated. Advantageously the time involved for dry-etching semiconductor wafers having a thickness of 50 μm or less, however, is short enough to assure that semiconductor wafers be diced quickly.

In case that semiconductor wafers have crosswise streets S covered with a material which cannot be removed by dry etching, the laser beam is preliminarily projected to the covering layer to remove portions of the covering layer corresponding to the crosswise streets, thereby permitting the semiconductor wafers to be diced by dry etching.

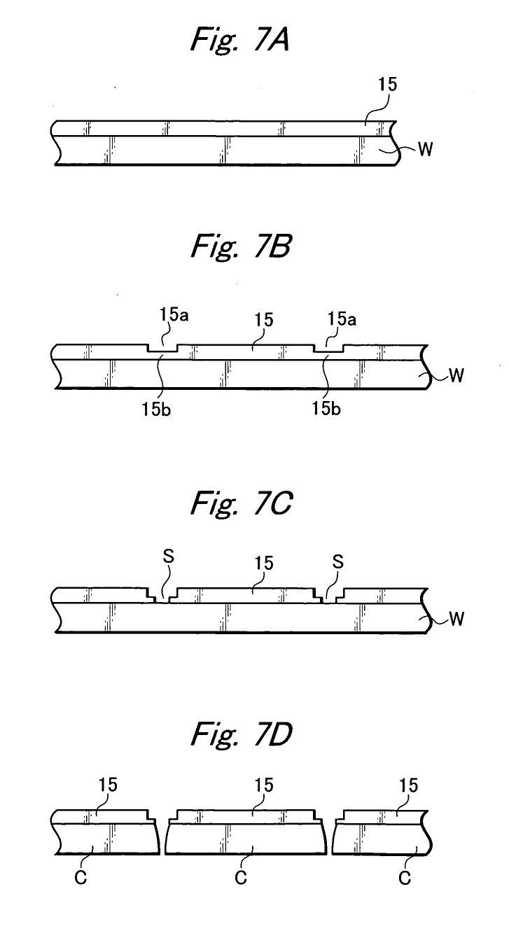

FIGS. 7A to 9 show another example of practicing the present invention. Specifically, FIG. 7A shows the state of a semiconductor wafer W just after the masking step is finished; FIG. 7B shows the state of the semiconductor wafer in the course of the selective mask-removing step; FIG. 7C shows the state of the semiconductor wafer W just after the selective mask-removing step is finished; and FIG. 7D shows the state of the semiconductor wafer W just after the dry etching step is finished.

At the masking step a masking member 15 is formed on the semiconductor wafer in the same way as described above and shown in FIG. 2.

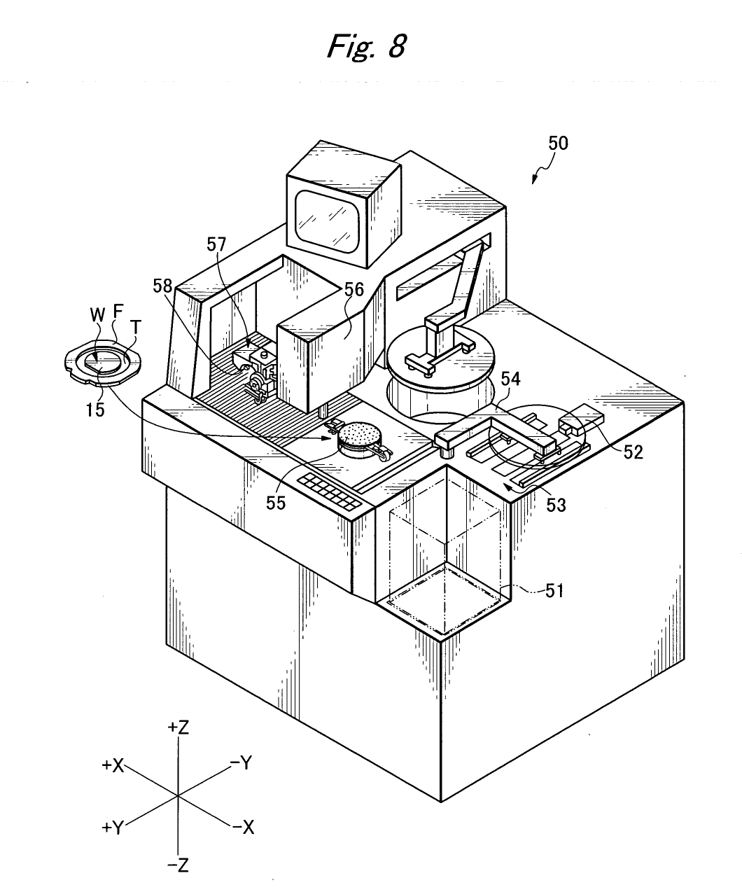

At the selective mask-removing step, a cutting machine 50 of FIG. 8 is used to make grooves 15a in the portion of the masking member 15 (see FIG. 7B), which lie in alignment with the underlying crosswise streets S.

In this cutting machine 50, a plurality of the semiconductor wafers W each of which is combined with a frame F as a whole unit via an adhesive tape T and covered the front face with the masking member 15 are stored in the cassette 51.

The semiconductor wafer W combined with a frame F as a whole unit and covered the front face with the masking member 15 is transported one by one to a tentative depository 53 by a transporting means 52 and transported by a transfer means 54 while being sucked thereto to a chuck table 55 to be held thereon.

Then, the chuck table 55 is moved in the +X-direction, and the semiconductor wafers W is put below an alignment means 56, which a selected street is detected. A rotary blade 58 of a cutting means 57 is put in alignment with the so detected street in respect of the Y-axial direction. If the masking member 15 is a semi-transparent, infrared rays are used to pass through the masking member 15 for detecting a selected street.

After the required alignment is finished, the chuck table 55 is moved further in the +X-direction, allowing the rotary blade 58 to cut the linear portion of masking member lying on the detected street while the rotary blade 58 descends and rotates at a high speed.

The rotary blade 58 is precisely controlled in respect of the cut depth in the masking member 15, thus leaving the constant thickness 15b between the bottom of the groove 15a and the upper surface of the semiconductor wafer W, as shown in FIG. 7B.

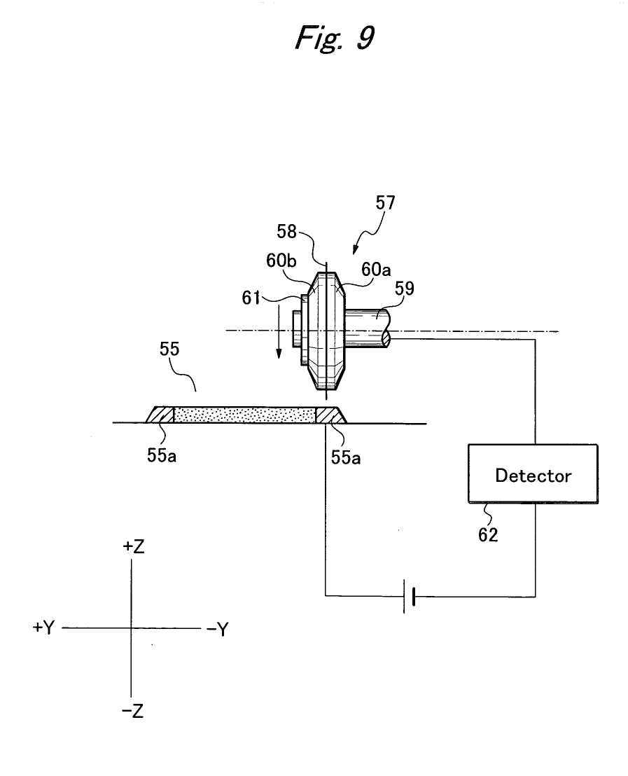

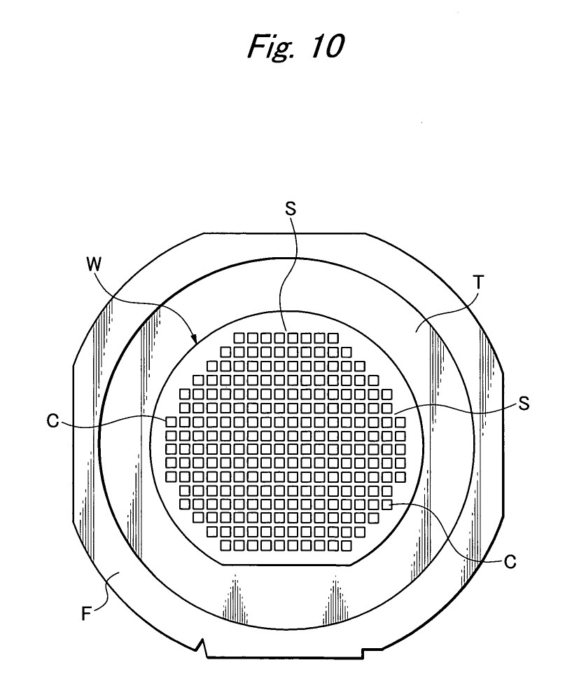

To control the cutting depth by the rotary blade 58 with high precision, it is necessary to set a reference position for the cutting means 57. Referring to FIG. 9, the cutting means 57 has the rotary blade 58 fixed to its spindle 59 via flanges 60a, 60b and a nut 61, and the chuck table 55 has a metal ring 55a fixed to its circumference. A conduction detector 62 is connected between the cutting means 57 and the conductive ring 55a of the chuck table 55 to detect the current flowing therebetween when the descending rotary blade 58 is put in contact with the conductive ring 55a, and then, the position of the cutting means 57 is used as a reference position in the Z-axial direction.

The upper surface of the conductive ring 55a is coplanar with the upper surface of the chuck table 55, and the rear face of the semiconductor wafer W is sucked on the chuck table 55 without any gap therebetween. Therefore, each and every groove 15a can be exactly cut by the rotary blade 58 to precisely leave the exact constant remaining thickness 15b, provided that the Z-axial position of the descending rotary blade 58 is controlled relative to the reference position.

Every time the cutting means 57 is driven the street-to-street distance in the Y-axial direction, the chuck table 55 is reciprocated in the X-axial direction, thereby making a groove 15a in the X-axial direction to leave the constant remaining thickness 15b which runs on a corresponding one of the X-axial streets.

After all the grooves 15a are made in the X-axial direction, the chuck table 55 is rotated 90 degrees, and another grooves 15a are made in the masking member 15 to leave the constant remaining thickness 15a in the same way as described above. Thus, the crosswise portions of the masking member 15 lying on the crosswise streets S of the semiconductor wafer W are removed to leave the constant thickness 15b (selective mask-removing step).

Next, the laser beam is projected to the bottom of the grooves 15a, i.e. the remaining thickness 15b in the same way as described with reference to FIG. 3 to completely remove the remaining thickness 15b as seen from FIG. 7C (selective mask-removing step).

Making grooves 15a to precisely leave the exact constant thickness of masking material 15b permits the crosswise portions of the masking member 15 to be completely removed by the laser beam without the necessity of changing or varying the scanning speed of the laser beam and its operating voltage even if the masking member 15 is not completely flat or is irregular on the surface.

Next, the dry-etching apparatus 30 as shown in FIGS. 4 to 6 is used to dry-etch the crosswise streets S of the semiconductor wafer W, separating it into semiconductor chips C, as shown in FIG. 7D.

In the above-described embodiments, the dry-etching treatment is used as the chemical etching. Wet-etching treatment, however, may be equally used. For example, semiconductor wafers may be soaked in a fluoride bath, as wet-etching treatment.

### INDUSTRIAL APPLICABILITY

As is described above, the method of dicing semiconductor wafers according to the present invention comprises the step of: masking the front face of each semiconductor wafer on which a circuit pattern is formed; removing the crosswise portions of the masking member which are in alignment with the underlying crosswise streets of the semiconductor wafer, with use of a laser beam; and chemical-etching the exposed crosswise streets to divide the semiconductor wafer into separate chips. The semiconductor chips thus provided are free of cracks, and are high in flexural strength. Particularly, if multi-layered semiconductor wafers with interlayer insulating films are diced, advantageously use of the laser beam causes no destructive force to be applied to the interlayer insulating films, and therefore, there is no fear of interlayer insulating films being peeled off as in a mica plate.

1. A method for dicing a semiconductor wafer having regions defined by crosswise streets into separate chips, each of the regions having a circuit pattern formed therein, comprising:
a masking step of masking the semiconductor wafer with a masking member to cover the front face of the semiconductor wafer on which the circuit patterns are formed;
a selective mask-removing step of irradiating a laser beam to selectively remove crosswise portions of the masking member which are exactly aligned with the underlying crosswise streets of the semiconductor wafer; and
a chemical etching step of chemically etching the semiconductor wafer having the crosswise streets unmasked, whereby the crosswise streets are permitted to erode so that the semiconductor wafer is divided into chips.

2. A method for dicing a semiconductor wafer into separate chips according to claim 1, wherein the selective mask-removing step includes the steps of: prior to crosswise removal of the masking member with the laser beam, making grooves along the underlying crosswise streets in the masking member to leave a constant thickness of masking member remaining under the crosswise grooves; and irradiating the laser beam to bottoms of the crosswise grooves to remove the remaining thickness of the masking member.

3. A method for dicing a semiconductor wafer into separate chips according to claim 1, wherein the semiconductor wafer has a plurality of circuit-patterned laminations and interlayer insulating films both interleaved with each other on its substrate.

4. A method for dicing a semiconductor wafer into separate chips according to claim 1, wherein if a cover layer which cannot be removed by the chemical etching is formed on the crosswise street pattern, the laser beam is irradiated to the cover layer for selective removal in the selective mask-removing step, thereby exposing the crosswise streets prior to the chemical etching step.

5. A method for dicing a semiconductor wafer into separate chips according to claim 1, wherein the chemical etching in the chemical etching step is dry etching with use of a fluoride gas.

6. A method for dicing a semiconductor wafer into separate chips according to claim 1, wherein the semiconductor wafer to be diced has a thickness of 50 μm or less.
